(19) United States
(12) Patent Application Publication
(10) Pub. No.: US 2025/0329612 A1
(43) Pub. Date: Oct. 23, 2025

(54) SEMICONDUCTOR MODULE AND SEMICONDUCTOR DEVICE

(71) Applicant: FUJI ELECTRIC CO., LTD., Kawasaki-shi (JP)

(72) Inventor: Kensuke MATSUZAWA, Kawasaki-shi (JP)

(73) Assignee: FUJI ELECTRIC CO., LTD., Kawasaki-shi (JP)

(21) Appl. No.: 19/065,239

(22) Filed: Feb. 27, 2025

(30) Foreign Application Priority Data
Apr. 23, 2024 (JP) 2024-069641

(51) Int. Cl. H01L 23/473; H01L 23/40; H01L 23/538

(52) U.S. Cl. CPC H01L 23/473; H01L 23/4006; H01L 23/5385

(57) ABSTRACT

A semiconductor module includes a cooler including a heat dissipation base and a plurality of heat dissipation fins disposed on a lower surface of the hear dissipation base, a substrate disposed on an upper surface of the hear dissipation base, having a semiconductor element mounted thereon, a water jacket configured to allow cooling water to flow through the plurality of heat dissipation fins when attached to a lower surface side of the cooler, a sealing part disposed on the lower surface of the heat dissipation base. The sealing part has a shape of recess accommodating the heat dissipation fins, the sealing part integrally having a sealing portion in contact with the lower surface of the heat dissipation base and extending away from heat dissipation fins, a bottom portion facing tips of the heat dissipation fins, and a plurality of connection portions each connecting the sealing portion to the bottom portion.

### CROSS-REFERENCE TO RELATED APPLICATION

This application is based upon and claims the benefit of priority to Japanese Patent Application No. 2024-069641, filed on Apr. 23, 2024, the entire contents of which are incorporated herein by reference.

### BACKGROUND OF THE INVENTION

### 1. Technical Field

The present invention relates to a semiconductor module including a cooler, and a semiconductor device including the semiconductor module and a water jacket.

### 2. Description of the Related Art

In a semiconductor device used for a power conversion device such as an inverter device, there is known a semiconductor device in which cooling water flows through a plurality of heat dissipation fins in a water jacket in order to cool a semiconductor element by heat dissipation (refer to, for example, JP 7160216 B2, WO 2012/114475 A, WO 2014/045758 A, and JP 2007-110025 A). A clearance is provided between the plurality of heat dissipation fins and the water jacket in order to avoid contact between the plurality of heat dissipation fins and the water jacket due to variations in dimensions at the time of manufacture.

### SUMMARY OF THE INVENTION

As the clearance between the plurality of heat dissipation fins and the water jacket increases, a proportion of cooling water passing through a space between the heat dissipation fins decreases, resulting in deterioration in cooling performance. In addition, in the clearance, a local battery due to a potential difference is formed, and a corrosion product is generated. Even when the corrosion product is clogged between the heat dissipation fins, cooling performance deteriorates. However, when a member for closing the clearance is disposed, a structure becomes complicated, and it takes time and effort to assemble.

An object of the present invention is to provide a semiconductor module and a semiconductor device capable of improving cooling performance and preventing corrosion with a simple configuration and with easy assembly.

In one aspect, a semiconductor module includes a semiconductor element, a substrate, a cooler, and a sealing material. The semiconductor element is mounted on the substrate. The cooler includes a heat dissipation base and a plurality of heat dissipation fins located on a side of the heat dissipation base, the side being opposite to the substrate, in which the cooler is attached to a water jacket configured to allow cooling water to flow through the plurality of heat dissipation fins. The sealing material integrally incudes a sealing portion in contact with a surface of the heat dissipation base of the cooler, the surface being located on the side opposite to the substrate, the sealing portion extending to a side opposite to the plurality of heat dissipation fins, a bottom portion having a portion facing tips of the plurality of heat dissipation fins, and connection portions each connecting the sealing portion to the bottom portion.

According to the above aspect, in a semiconductor module and a semiconductor device, it is possible to improve cooling performance and prevent corrosion with a simple configuration and with easy assembly.

### BRIEF DESCRIPTION OF THE DRAWINGS

FIG. 1 is a front view illustrating an internal structure of a semiconductor device in an embodiment;

FIG. 2 is a perspective view of a sealing material and a water jacket in the embodiment;

FIG. 3 is an exploded perspective view of the sealing material and the water jacket in the embodiment;

FIG. 4A is a graph for explaining a difference in thermal resistance depending on the presence or absence of the sealing material;

FIG. 4B is a plan view illustrating regions 1 to 6 illustrated in FIG. 4A;

FIG. 5 is an exploded perspective view of a sealing material and a water jacket in a first modification of the embodiment;

FIG. 6 is an exploded perspective view of a sealing material and a water jacket in a second modification of the embodiment;

FIG. 7 is an exploded perspective view of a sealing material and a water jacket in a third modification of the embodiment;

FIG. 8 is an exploded perspective view of a sealing material and a water jacket in a fourth modification of the embodiment;

FIG. 9 is a perspective view of an O-ring and a water jacket in a comparative example;

FIG. 10 is a front view illustrating an internal structure of a semiconductor device for explaining cooling water flowing through a clearance in the comparative example; and

FIG. 11 is a front view illustrating the internal structure of the semiconductor device for explaining a corroded portion in the comparative example.

### DETAILED DESCRIPTION

Hereinafter, a semiconductor module and a semiconductor device according to an embodiment of the present invention will be described with reference to the drawings. Note that the present invention is not limited to the embodiment described below, and thus appropriate modifications can be made without departing from the gist thereof.

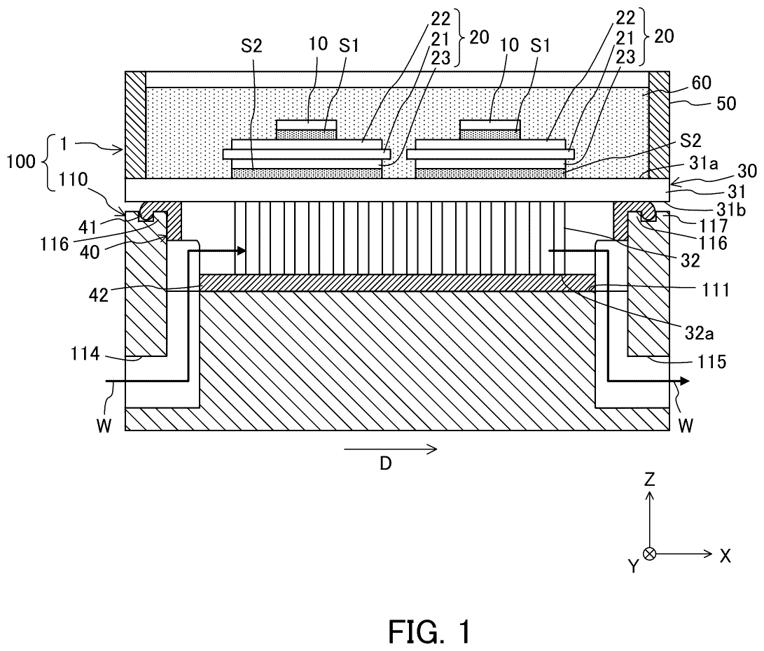

FIG. 1 is a front view illustrating an internal structure of a semiconductor device 100 according to an embodiment.

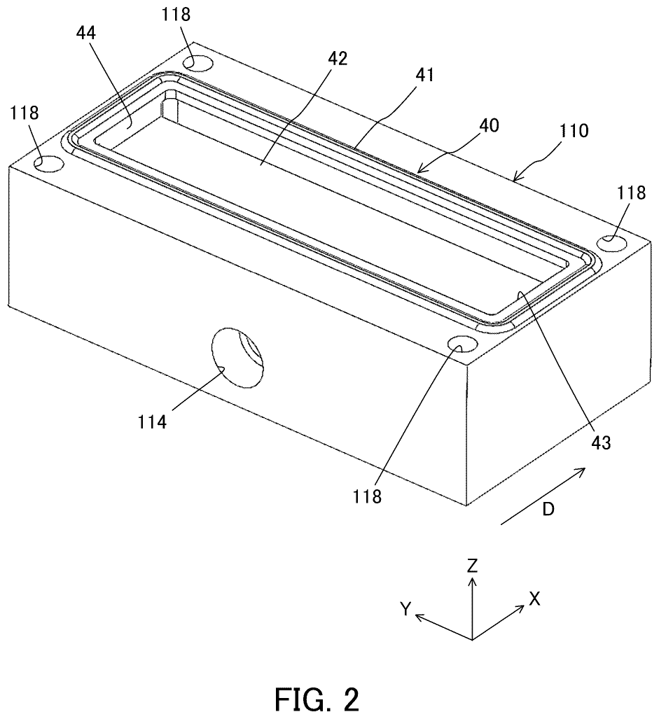

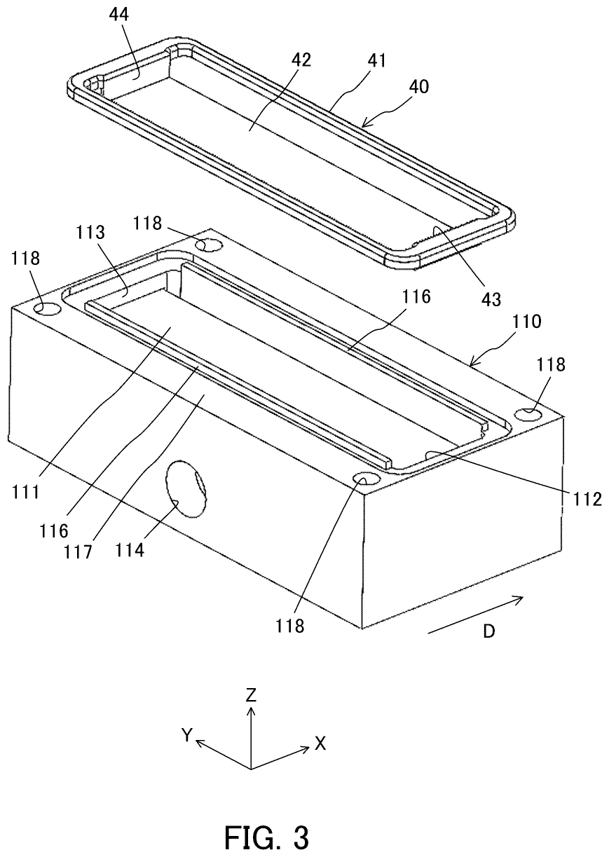

FIGS. 2 and 3 are a perspective view and an exploded perspective view of a sealing material (sealing part) 40 and a water jacket 110.

In the X direction, the Y direction, and the Z direction illustrated in FIGS. 1 to 3 and FIGS. 5 to 11 described later, the thickness direction of the semiconductor element 10 is defined as the Z direction, and a flow direction D of a cooling water W in the X direction and the Y direction that are orthogonal to the Z direction and are orthogonal to each other is defined as the positive side in the X direction. In some cases, the X direction may be referred to as a left-and-right direction, the Y direction may be referred to as a forward-and-rearward direction, and the Z direction may be referred to as an upward-and-downward direction. Such directional terms are used for convenience of description. Thus, depending on the installation posture of the semiconductor device 100, the correspondence relationship with the X direction, the Y direction, and the Z direction varies.

A semiconductor module 1 according to the present embodiment is applied, for example, to a power converter, such as a power control unit, and serves as a power semiconductor module configuring an inverter circuit. The application of the semiconductor module 1 and the semiconductor device 100 including the semiconductor module 1 and the water jacket 110 is any application, but for example, the semiconductor module 1 and the semiconductor device 100 are used as an inverter device of an on-vehicle or industrial motor.

The semiconductor device 100 illustrated in FIG. 1 includes the semiconductor module 1 and the water jacket 110. The semiconductor module 1 includes two semiconductor elements 10, two stacked substrates 20, a cooler 30, the sealing material (sealing part) 40, a case 50, and a sealing resin 60.

The water jacket 110 is attached to a lower portion of the cooler 30 by respectively fastening, for example, screws in fastening holes 118 respectively formed in four corners on the upper surface illustrated in FIG. 2. Each of the screws preferably fastens the case 50, the cooler 30, and the water jacket 110. The water jacket 110 is provided, for example, in an inverter case of the inverter device.

The water jacket 110 is made of, for example, a die-casting material such as an aluminum alloy (ADC12). The water jacket 110 has a rectangular parallelepiped shape that is open at the upper portion thereof, and as illustrated in FIG. 1, the cooling water W flows through the inside that accommodates a plurality of heat dissipation fins 32. The cooling water W flows in the flow direction D in the right direction (positive side in the X direction) so as to pass through the plurality of heat dissipation fins 32 of the cooler 30, and heat is transferred from the plurality of heat dissipation fins 32 to the cooling water W. The cooling water W is, for example, a liquid such as water containing additives, such as antifreeze agents, rust inhibitors, and antioxidants.

An inner bottom surface 111 of the water jacket 110 through which the cooling water W flows faces tips 32a of the plurality of heat dissipation fins 32 via the sealing material 40. Since the front and rear side surfaces 112 and 113 (refer to FIG. 3) inside the water jacket 110 extend in the XZ plane, the cooling water W extends in the flow direction D (positive side in the X direction) in which the cooling water W flows through the plurality of heat dissipation fins 32. In the present embodiment, the flow direction D is parallel to the lateral direction (the X direction) of the water jacket 110 in plan view, but may be parallel to the longitudinal direction (the Y direction) of the water jacket 110 in plan view.

As illustrated in FIG. 1, an introduction path 114 configured to allow the cooling water W to be introduced into the water jacket 110 is provided from the left end to the inside of the water jacket 110. In addition, a discharge path 115 configured to allow the cooling water W to be discharged from the water jacket 110 is provided from the inside to the right end of the water jacket 110. The introduction path 114 extends horizontally from the left end of the water jacket 110, is bent vertically upwards from the middle, and is connected to the inside of the water jacket 110. In addition, the discharge path 115 extends vertically downwards from the inside of the water jacket 110, is horizontally bent from the middle, and extends to the right end of the water jacket 110. The introduction path 114 and the discharge path 115 may connect the inside of the water jacket 110 to the lower end of the water jacket 110.

As illustrated in FIG. 3, the upper surface of the water jacket 110 is provided such that inner walls 116 that hold the inner peripheral side of a sealing portion 41 respectively protrude toward a side of a heat dissipation base 31 side (upwards) from inner peripheral edges of portions having regions (right portion and left portion) respectively disposed therein and not connected to side walls 43 and 44 in the sealing portion 41 of the sealing material 40 to be described later.

On the upper surface of the water jacket 110, the inner wall 116 is not provided at the portion of the sealing portion 41 where the regions (front portion and rear portion) respectively connected to the side walls 43 and 44 are disposed. Therefore, in the water jacket 110, the portions (that is, regions on the inner peripheral side of an outer wall 117 on the upper surface of the water jacket 110) at which the regions respectively connected to the side walls 43 and 44 are disposed in the sealing portion 41 of the sealing material 40 form the same plane.

In addition, a portion of the upper surface of the water jacket 110, which is located on the outer peripheral side of the sealing material 40 functions as the outer wall 117 for holding the outer peripheral side of the sealing portion 41 of the sealing material 40. It can also be considered that a concave portion is provided between the inner wall 116 and the outer wall 117 on the upper surface of the water jacket 110. In the sealing portion 41 of the sealing material 40, a convex portion to be inserted between the inner wall 116 and the outer wall 117 (concave portion) may be provided so as to protrude downwards.

The semiconductor element 10 of the semiconductor module 1 illustrated in FIG. 1 is mounted on the stacked substrate 20 (circuit board 22) by a bonding material S1 which is, for example, solder, and is connected to another circuit board by a conductor wire, a metal wiring board, or the like. For example, the semiconductor element 10 is formed in a square or rectangular shape in plan view with a semiconductor substrate based on silicon (Si), silicon carbide (SiC), gallium nitride (GaN), or diamond.

As the semiconductor element 10, a switching element such as an insulated gate bipolar transistor (IGBT) and a power metal oxide semiconductor field effect transistor (power MOSFET), and a diode such as a freewheeling diode (FWD) are used. The switching element and the diode may be connected in anti-parallel. As the semiconductor element 10, used may be a reverse conducting (RC)-IGBT element of an IGBT and an FWD in unification, a power MOSFET element, or a reverse blocking (RB)-IGBT element highly resistant to a reverse bias.

The semiconductor elements 10 are respectively mounted on the two stacked substrates 20. The stacked substrate 20 is an example of a substrate on which the semiconductor element 10 is mounted. The stacked substrate 20 includes, for example, a direct copper bonding (DCB) substrate, an active metal brazing (AMB) substrate, or a metal base substrate. The stacked substrate 20 is formed in, for example, a rectangular shape in plan view. Each of the two stacked substrates 20 includes an insulating plate 21, a circuit board 22, and a heat dissipation plate 23.

The insulating plate 21 is formed of, for example, a ceramic material such as aluminum oxide (Al₂O₃), aluminum nitride (AlN), silicon nitride (Si₃N₄), a composite material of aluminum oxide and zirconium oxide (ZrO₂), or a sealing material such as a resin material such as epoxy, or an epoxy resin material using a ceramic material as a filler. The insulating plate 21 may be referred to as an insulating layer or an insulating film.

The circuit board 22 is formed on the upper surface of the insulating plate 21. The number of the circuit boards 22 may be any number of one or more. The circuit boards 22 is a metal layer such as copper foil, and for example, a plurality of circuit boards are formed in an island shape in a mutually electrically insulated state on the insulating plate 21. The circuit board 22 may be referred to as a circuit pattern, a circuit layer, a wiring board, a wiring pattern, a wiring layer, or the like.

The heat dissipation plate 23 is formed on the lower surface of the insulating plate 21. The heat dissipation plate 23 is formed of, for example, a metal plate having good thermal conductivity such as copper or aluminum. The heat dissipation plate 23 is bonded to an upper surface 31a of the heat dissipation base 31 of the cooler 30 by a bonding material S2 which is, for example, solder. The heat dissipation plate 23 may be referred to as a heat dissipation layer or the like.

Although the two semiconductor elements 10 and the two stacked substrates 20 described above are disposed on the upper portion of the heat dissipation base 31, for example, three sets of semiconductor units forming a three-phase inverter circuit may be disposed by using the two semiconductor elements 10 and the two stacked substrates 20 as one set of semiconductor units. As described above, the number of semiconductor elements 10 and stacked substrates 20 is not particularly limited. Further, the two semiconductor elements 10 and the two stacked substrates 20 are disposed in the X direction, but may be arranged in a line in the Y direction. Furthermore, the plurality of semiconductor elements 10 used in the three sets of semiconductor units forming the three-phase inverter circuit may be disposed in a line in the Y direction.

The cooler 30 includes the heat dissipation base 31 and a plurality of heat dissipation fins 32. The cooler 30 is made of, for example, a copper material or an aluminum material.

The heat dissipation base 31 has, for example, a rectangular plate shape. As described above, the stacked substrate 20 (heat dissipation plate 23) is bonded to the upper surface 31a, which is an example of the first surface of the heat dissipation base 31, by the bonding material S2. The heat dissipation base 31 can be referred to as a top plate of the cooler 30. Note that the stacked substrate 20 may be bonded to the upper surface 31a of the heat dissipation base 31 via, for example, a heat dissipation flat plate or the like.

The plurality of heat dissipation fins 32 protrude from a lower surface 31b, which is an example of the second surface of heat dissipation base 31. As a result, the plurality of heat dissipation fins 32 are located on a side of the heat dissipation base 31 (negative side in the Z direction), in which the side is opposite to the stacked substrate 20. In addition, the heat dissipation fins 32 can be said to be open fins exposed to the outside of the cooler 30 below the heat dissipation base 31. The plurality of heat dissipation fins 32 may be formed to be integrated with the heat dissipation base 31, or may be formed by being fixed to the heat dissipation base 31. The plurality of heat dissipation fins 32 are, for example, pin fins and each have a cylindrical shape. A plurality of heat dissipation fins 32 are arranged in each of the X direction and the Y direction. Since the heat exchange performance of the plurality of heat dissipation fins 32 increases as the flow velocity of the cooling water W passing through the heat dissipation fins 32 increases, the density and arrangement of the heat dissipation fins 32 are designed in consideration of the balance with the allowable pressure of a pump circulating the cooling water W.

The plurality of heat dissipation fins 32 are not limited to cylindrical pin fins, but may be pin fins having other shapes such as a polygonal column shape, flat plate-shaped fins (plate fins), curved plate-shaped fins (corrugated fins), or the like, and are not particularly limited.

As illustrated in FIG. 3, the sealing material 40 integrally has the sealing portion 41, a bottom portion 42, and the side walls 43 and 44 facing each other as an example of a connection portion. The sealing material 40 has an insulating property. The sealing material 40 is preferably made of, for example, a rubber material (elastic body) such as silicone rubber or ethylene propylene rubber. Note that the sealing material 40 may be fixed by being fitted into the water jacket 110, or may be fixed to the water jacket 110 or the cooler 30 by adhesion or the like.

The sealing portion 41 extends to the side opposite to the heat dissipation fin 32 and is interposed between the heat dissipation base 31 of the cooler 30 and the water jacket 110 so as to surround an opening portion of the upper surface of the water jacket 110. That is, the lower surface 31b of the heat dissipation base 31 and the water jacket 110 come into contact with the sealing portion 41 to seal the inside of the water jacket 110. The sealing portion 41 can be regarded as an O-ring (seal ring) having a rectangular frame shape.

As illustrated in FIG. 1, the bottom portion (bottom wall) 42 of the sealing material 40 is disposed on at least a part of the bottom surface 111 inside the water jacket 110 and has a flat plate shape. The bottom portion 42 has a portion facing the tips 32a of the plurality of heat dissipation fins 32. The bottom portion 42 may be disposed on the bottom surface 111 of the water jacket 110 so as to face the tips 32a of all the heat dissipation fins 32. However, the bottom portion 42 may be disposed so as to face the tips 32a of only some of the heat dissipation fins 32.

When the plurality of heat dissipation fins 32 extend downwards (the negative side in the Z direction) due to thermal expansion, the bottom portion 42 is preferably made of an elastic body as described above in order to suppress hindrance of sealing performance between the cooler 30 and the water jacket 110 and deformation of the heat dissipation fins 32 due to the plurality of heat dissipation fins 32 (cooler 30) being pushed upwards by the bottom portion 42. The thermal expansion may cause not only the expansion of the heat dissipation fin 32 on the negative side in the Z direction but also the expansion of the heat dissipation fin 32 in the XY direction and the expansion of the water jacket 110 toward the heat dissipation fin 32 side. Therefore, the entire sealing material 40 is preferably made of an elastic body as described above, and can follow the thermal deformation of the plurality of heat dissipation fins 32 and the water jacket 110.

The side wall 43 (a first side wall) is disposed on at least a part of the side surface 112, which is the front surface inside the water jacket 110, and has a flat plate shape. The side wall 44 (a second side wall) is disposed on at least a part of the side surface 113, which is the rear surface inside the water jacket 110, and has a flat plate shape. The side walls 43 and 44 extend in the flow direction D in which the cooling water W flows through the plurality of heat dissipation fins 32, and have portions facing the plurality of heat dissipation fins 32. The side walls 43 and 44 are preferably formed to have a size equal to or larger than a size of a region where the plurality of heat dissipation fins 32 are disposed in the X direction. As illustrated in FIG. 1, a part of the sealing portion 41 is located over the right side surface and the left side surface of the inside of the water jacket 110.

Each of the side walls 43 and 44 is an example of a connection portion that connects the sealing portion 41 to the bottom portion 42. The connection portion may be one of the side walls 43 and 44, may be disposed on the left side surface or the right side surface of the inside of the water jacket 110, or may be a belt-like (string-like) portion longer in the Z direction than in the X direction and the Y direction. The side walls 43 and 44 are disposed to face each other, and the plurality of heat dissipation fins 32 are surrounded by the bottom portion 42 and the side walls 43 and 44.

The thickness (the Z direction) of the bottom portion 42 may coincide with a clearance between the plurality of heat dissipation fins 32 and the bottom surface 111 of the water jacket 110 at a temperature before heat generation of the semiconductor element 10. In addition, the thicknesses (the Y direction) of the side walls 43 and 44 may coincide with clearances between the plurality of heat dissipation fins 32 and the side surfaces 112 and 113 of the water jacket 110 at a temperature before heat generation of the semiconductor element 10.

At least one of the bottom portion 42, the side wall 43, and the side wall 44 may be partially thicker or thinner in thickness. For example, by further narrowing the clearance between the heat dissipation fin 32 and the water jacket 110, the thicknesses of the bottom portion 42 and the side walls 43 and 44 may partially increase so that the cooling water W easily passes between some of the heat dissipation fins 32, or conversely, the thickness of the bottom portion 42 may partially decrease below the heat dissipation fin 32 having a high temperature that easily extends downwards (the negative side in the Z direction) due to thermal expansion.

The case 50 has a rectangular frame shape so as to surround the two semiconductor elements 10 and the two stacked substrates 20 on the upper portion of the heat dissipation base 31. The case 50 is made of, for example, resin.

The sealing resin 60 fills the inside of the case 50 so as to cover the two semiconductor elements 10 and the two stacked substrates 20. The sealing resin 60 is made of, for example, a resin or a gel. The sealing resin 60 may be formed by transfer molding or potting.

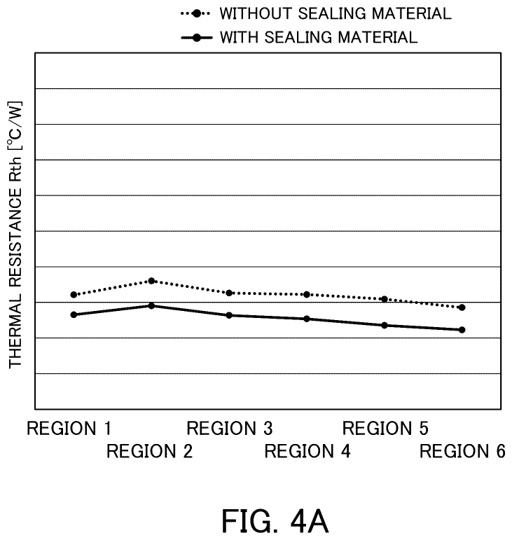

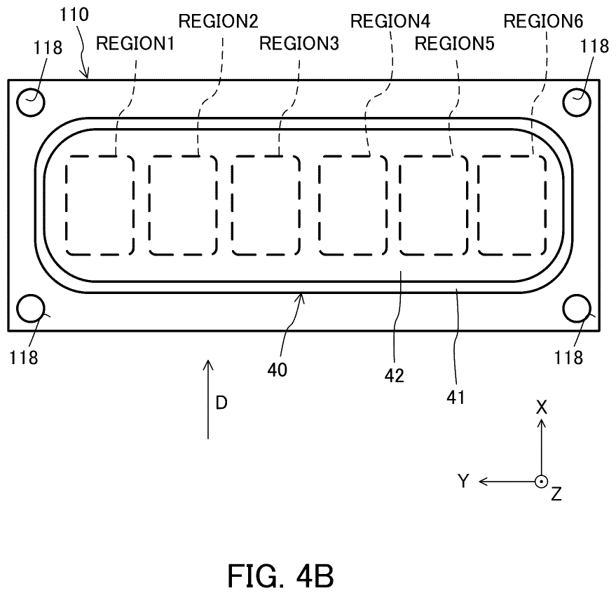

FIG. 4A is a graph for explaining a difference in thermal resistance Rth depending on the presence or absence of the sealing material 40. FIG. 4B is a plan view illustrating regions 1 to 6 to be described later illustrated in FIG. 4A.

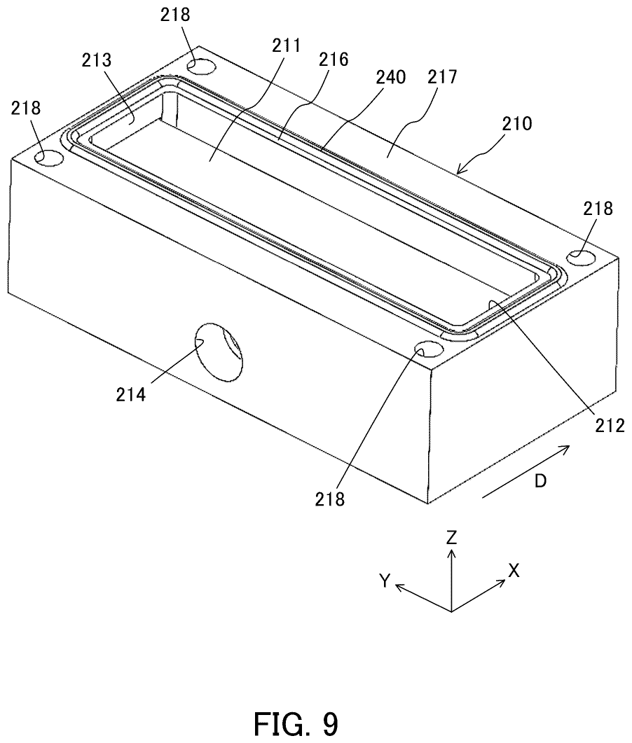

“No sealing material” illustrated in FIG. 4A is an example in which an O-ring 240 interposed between the heat dissipation base 31 and the water jacket 110 is arranged instead of the sealing material 40, as illustrated in FIGS. 9 to 11 of a comparative example. “With sealing material” is an example in which the sealing material 40 is disposed, as illustrated in FIGS. 1 to 3 of the present embodiment.

Thermal resistance Rth [° C./W] is thermal resistance from the bonding material S1 for bonding the semiconductor element 10 to the stacked substrate 20 to the cooling water W. The regions 1 to 6 correspond to the regions 1 to 6 in FIG. 4B to be described later. The regions 1 to 6 illustrated in FIG. 4B are disposed in a line in the Y direction. In addition, each of the regions 1 to 6 is a region corresponding to a position at which one semiconductor element 10 is disposed.

As illustrated in FIG. 4A, when the sealing material 40 is disposed, the thermal resistance Rth is smaller in each region than that in a case where the O-ring 240 is disposed. It can be said that the thermal resistance Rth can be reduced in this manner because the sealing material 40 (the bottom portion 42 and the side walls 43 and 44) is disposed in the clearance between the plurality of heat dissipation fins 32 and the water jacket 110, so that the cooling water W easily passes through between the plurality of heat dissipation fins 32. As shown in FIG. 1, even when three sets of semiconductor units each including two semiconductor elements 10 arranged in the flow direction D (the X direction) of the cooling water W are disposed in the Y direction, the same effect can be obtained.

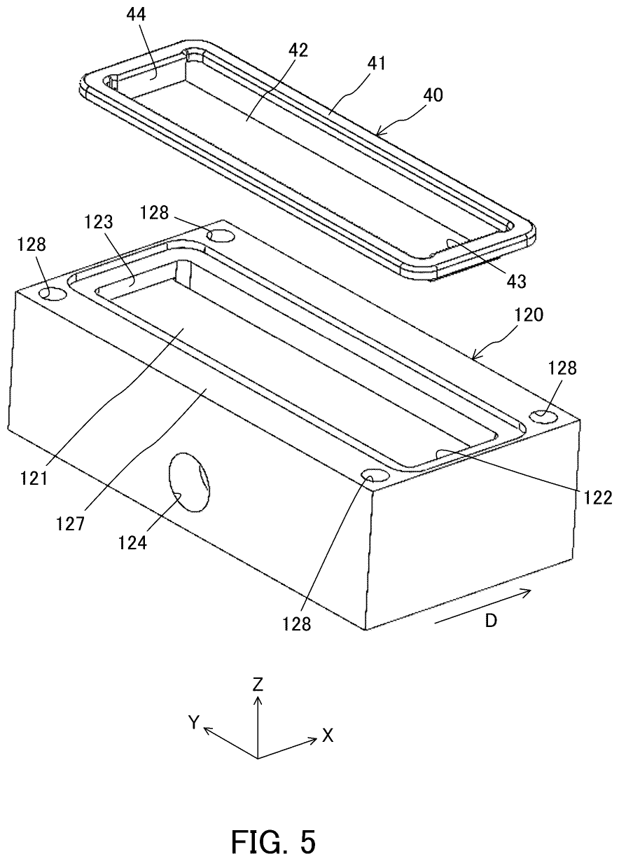

FIG. 5 is an exploded perspective view of a sealing material 40 and a water jacket 120 according to a first modification of the present embodiment.

The sealing material 40 illustrated in FIG. 5 can be similar to the above-described sealing material 40 illustrated in FIG. 3 and the like.

In the water jacket 120, two inner walls 116 of the water jacket 110 illustrated in FIG. 3 and the like are omitted. That is, similarly to the water jacket 110, the water jacket 120 includes a bottom surface 121, side surfaces 122 and 123, an introduction path 124, a discharge path (not illustrated), an outer wall 127, and four fastening holes 128.

In the water jacket 120, since the two inner walls 116 are omitted, portions at which the sealing portion 41 of the sealing material 40 is disposed (that is, regions on the inner peripheral side of the outer wall 127 on the upper surface of the water jacket 120) form the same plane (for example, a horizontal plane). It can also be considered that a concave portion is provided between the inside and the outer wall 127 on the upper surface of the water jacket 120.

Since the inner wall 116 is not provided in the water jacket 120, it is possible to omit the convex portion of the above-described sealing portion 41 inserted into the concave portion between the inner wall 116 and the outer wall 127.

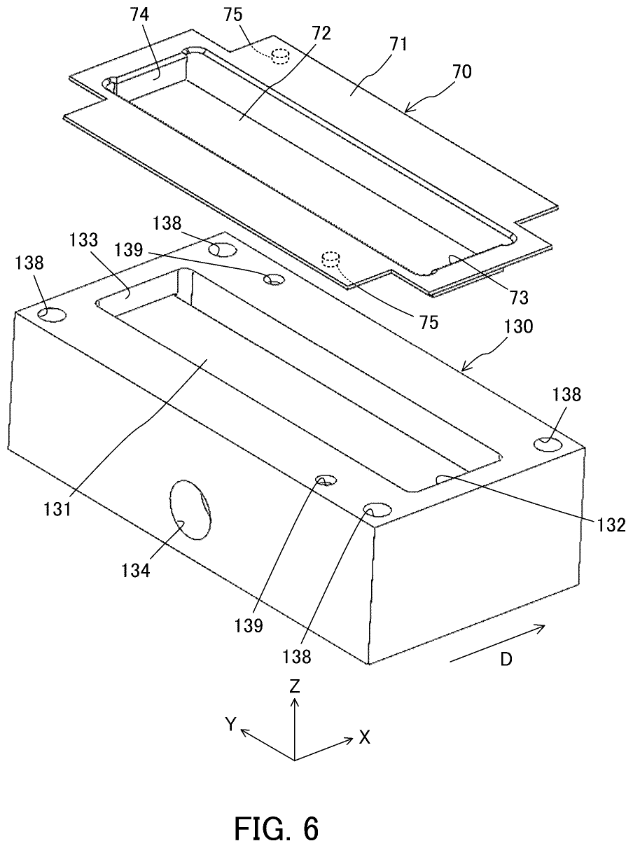

FIG. 6 is an exploded perspective view of a sealing material 70 and a water jacket 130 according to a second modification of the present embodiment.

The sealing material 70 illustrated in FIG. 6 includes a sealing portion 71, a bottom portion 72, side walls 73 and 74 as an example of a connection portion, and two jacket-side convex portions 75 (illustrated by broken lines which are curved lines).

The sealing portion 71 is interposed between the heat dissipation base 31 of the cooler 30 and the water jacket 130, and seals the inside of the water jacket 130. The sealing portion 71 has a flat plate frame shape expanding in a region avoiding the four fastening holes 138 on the upper surface of the water jacket 130.

The jacket-side convex portion 75 protrudes downwards (opposite side of the heat dissipation base 31) from the right rear portion and the left front portion of the bottom surface of the sealing portion 71. The two jacket-side convex portions 75 are respectively inserted into concave portions 139 provided on the upper surface of the water jacket 130.

The number of the jacket-side convex portions 75 may be any number of one or more. Instead of the jacket-side convex portion 75 or together with the jacket-side convex portion 75, a jacket-side concave portion, recessed upwards (heat dissipation base 31 side) and formed to allow the convex portion provided on the water jacket 130 to be inserted thereinto, may be provided. In addition, the sealing material 70 may be provided with at least one of a cooler-side convex portion inserted into a concave portion provided in the cooler 30 and a cooler-side concave portion into which a convex portion provided on the cooler 30 is inserted.

With respect to other matters, the sealing material 70 can be similar to the above-described sealing material 40 illustrated in FIG. 3 and the like.

In the water jacket 130, two inner walls 116 and outer walls 117 are omitted and two concave portions 139 are added as compared with the water jacket 110 illustrated in FIG. 3 and the like. That is, similarly to the water jacket 110, the water jacket 130 includes a bottom surface 131, side surfaces 132 and 133, an introduction path 134, a discharge path (not illustrated), and four fastening holes 138. The water jacket 130 has two concave portions 139 formed to allow the above-described jacket-side convex portions 75 to be respectively inserted thereinto.

In the water jacket 130, since the two inner walls 116 and the outer wall 117 are omitted, the entire upper surface of the water jacket 130 including the portion at which the sealing portion 71 of the sealing material 70 is disposed forms the same plane (for example, the horizontal plane).

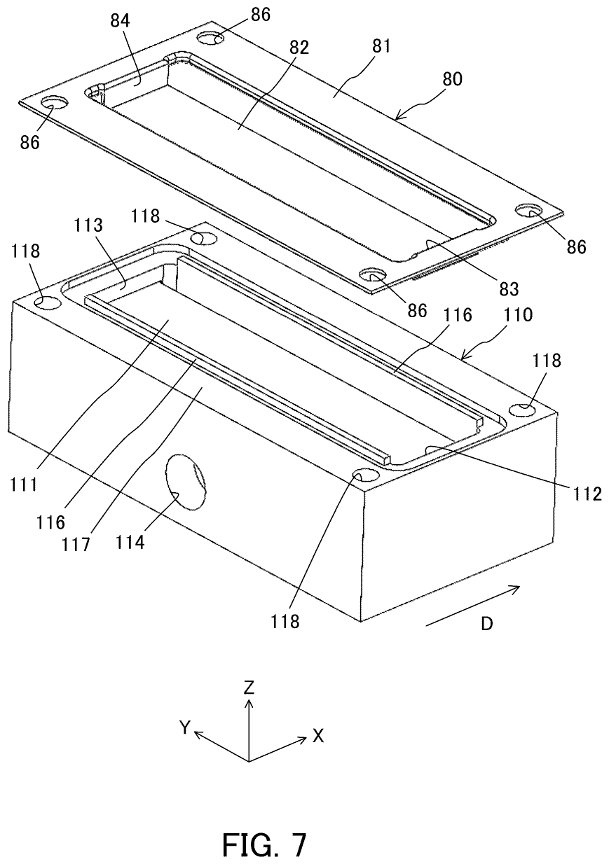

FIG. 7 is an exploded perspective view of a sealing material 80 and a water jacket 110 according to a third modification of the present embodiment.

The sealing material 80 illustrated in FIG. 7 includes a sealing portion 81, a bottom portion 82, side walls 83 and 84 as an example of a connection portion, and four through holes 86.

The sealing portion 81 is interposed between the heat dissipation base 31 of the cooler 30 and the water jacket 110, and seals the inside of the water jacket 110. The sealing portion 81 has a flat plate frame shape spreading over the entire upper surface of the water jacket 110.

The entire size of the sealing portion 81 in the X direction and the Y direction is, for example, the same size as the upper surface of the water jacket 110.

Screws for fastening the heat dissipation base 31 of the cooler 30 and the water jacket 110 (with the case 50) are respectively inserted into the four through holes 86. Although the through holes 86 are respectively provided at four corners of the sealing material 80 in plan view, the through holes may be respectively provided only at two corners facing each other in the diagonal direction among the four corners.

The water jacket 110 illustrated in FIG. 7 can be similar to the above-described water jacket 110 shown in FIG. 3 and the like.

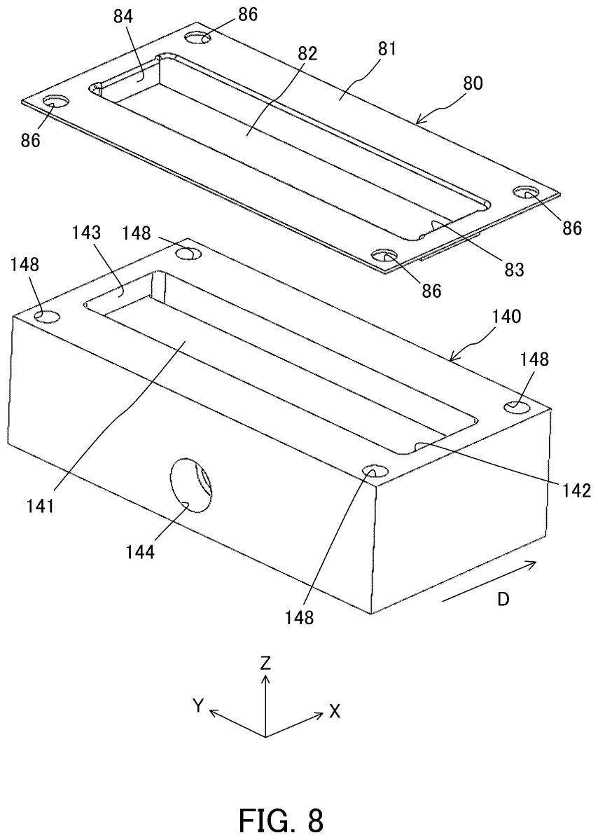

FIG. 8 is an exploded perspective view of a sealing material 80 and a water jacket 140 according to a fourth modification of the present embodiment.

The sealing material 80 illustrated in FIG. 8 can be similar to the above-described sealing material 80 illustrated in FIG. 7.

In the water jacket 140, two concave portions 139 are omitted in the water jacket 130 illustrated in FIG. 6. That is, similarly to the water jacket 130, the water jacket 140 includes a bottom surface 141, side surfaces 142 and 143, an introduction path 144, a discharge path (not illustrated), and four fastening holes 148.

Meanwhile, in the comparative example illustrated in FIGS. 9 to 11, the O-ring 240 is disposed instead of the sealing material 40. In addition, a water jacket 210 of a comparative example is different from the water jacket 110 illustrated in FIG. 3 and the like in that an inner wall 216 is provided over the entire inner peripheral edge of the upper surface of the water jacket 210 surrounding the inside of the water jacket 210. That is, the water jacket 210 has a bottom surface 211, side surfaces 212 and 213, an introduction path 214, a discharge path 215, an inner wall 216, an outer wall 217, and four fastening holes 218.

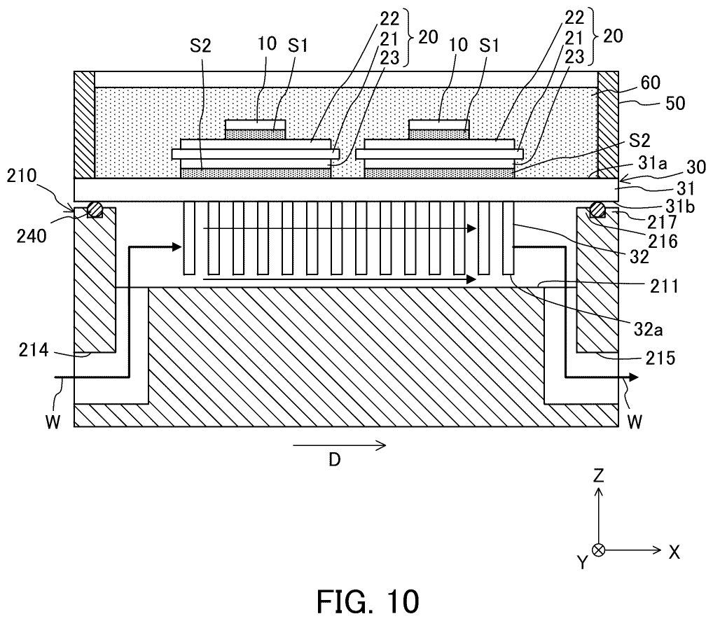

In the present comparative example, since the sealing material 40 is not disposed, the water passage resistance of the clearance between the plurality of heat dissipation fins 32 and the water jacket 210 (the bottom surface 211 and the side surfaces 212 and 213) is small. Therefore, as illustrated in FIG. 10, since the cooling water W flows in this clearance, the flow rate (flow velocity) of the cooling water W passing through the heat dissipation fins 32 is relatively reduced, and cooling performance cannot be sufficiently exhibited. Therefore, if a structure in which the cooling water W hardly flows through the clearance or high-accuracy processing for reducing tolerance is adopted, costs increase.

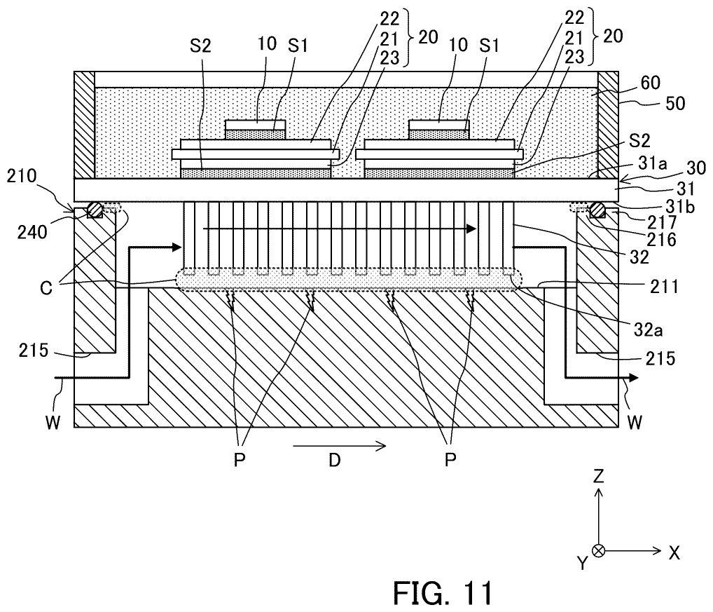

In the clearance between the plurality of heat dissipation fins 32 and the water jacket 210, when the plurality of heat dissipation fins 32 (coolers 30) are made of a copper material and the water jacket 210 is made of a die-casting material, a local battery caused by a potential difference between dissimilar metals is formed in a state of being close to each other and filled with the cooling water W, and a corrosion product such as aluminum hydroxide (Al(OH)₃) is generated. In particular, due to such corrosion of the water jacket 210, a corrosion product adheres between the plurality of heat dissipation fins 32 or between the heat dissipation base 31 and the inner wall 216 of the water jacket 210 as in a corroded portion C indicated by a broken line in FIG. 11, or local pitting P is formed in the water jacket 210.

In the present embodiment described above, the semiconductor module 1 includes the semiconductor element 10, the stacked substrate 20 which is an example of a substrate, the cooler 30, and the sealing material 40. The semiconductor element 10 is mounted on the stacked substrate 20. The cooler 30 includes the heat dissipation base 31 and the plurality of heat dissipation fins 32 located on a side of the heat dissipation base 31, in which the side is opposite to the stacked substrate 20, and the water jacket 110 configured to allow the cooling water W to flow through the plurality of heat dissipation fins 32 is attached to the cooler 30. The sealing material 40 is in contact with the lower surface 31b of the heat dissipation base 31 of the cooler 30 on the opposite side of the stacked substrate 20, and integrally includes the sealing portion 41 extending to the opposite side of the plurality of heat dissipation fins 32, the bottom portion 42 having a portion facing the tips 32a of the plurality of heat dissipation fins 32, and the side walls 43 and 44 (which are each an example of a connection portion) connecting the sealing portion 41 to the bottom portion 42.

In the present embodiment, the semiconductor device 100 includes the semiconductor module 1 and the water jacket 110.

In the semiconductor module 1 and the semiconductor device 100, the sealing material 40 is disposed in a clearance provided between the plurality of heat dissipation fins 32 and the water jacket 110 so as not to come into contact with each other due to variations in dimensions at the time of manufacture. Therefore, the cooling water W easily passes through between the plurality of heat dissipation fins 32, and cooling performance thereof can be improved. In addition, by disposing the sealing material 40 between the plurality of heat dissipation fins 32 and the water jacket 110, it is possible to suppress formation of a local battery due to a potential difference. Therefore, it is possible to suppress corrosion of the water jacket 110 and the plurality of heat dissipation fins 32, and occurrence of deterioration in cooling performance and pressure loss due to clogging of the deposited corrosion product between the plurality of heat dissipation fins 32. Furthermore, in the sealing material 40, the sealing portion 41 for sealing the inside of the water jacket 110 and the bottom portion 42 are formed to be integrated with each other. Therefore, the semiconductor module 1 and the semiconductor device 100 can have a simple configuration as compared with a case in which the sealing portion 41 and the bottom portion 42 are separated from each other. In addition, if the clearance is closed using the bottom portion 42 separated from the sealing portion 41, it takes time and effort to assemble the bottom portion 42 for fixing, positioning, and the like. Therefore, according to the present embodiment, it is possible to improve cooling performance and prevent corrosion with a simple configuration and with easy assembly. In addition, by improving the cooling performance (heat dissipation performance) as described above, it is possible to improve the output of the semiconductor module 1 and reduce the size thereof, to reduce the cost of the chip shrink, and to improve reliability by suppressing the heat generation temperature. In addition, since a design can be made without concern about contact between the heat dissipation fin 32 and the bottom surface 111 of the water jacket 110 and formation of a local battery, it is also possible to alleviate tolerance requirements regarding flatness of the heat dissipation fins 32 and the water jacket 110.

In addition, in the present embodiment, the connection portion connecting the sealing portion 41 to the bottom portion 42 of the sealing material 40 includes the side walls 43 and 44 disposed on at least a part of at least one of the side surfaces 112 and 113 at the inside of the water jacket 110 extending in the flow direction D in which the cooling water W flows through the plurality of heat dissipation fins 32.

As a result, not only the clearance between the tips 32a of the heat dissipation fins 32 and the bottom surface 111 of the water jacket 110 but also the clearance between the heat dissipation fins 32 and the side surfaces 112 and 113 of the water jacket 110 can be closed. Therefore, the cooling performance can be further improved. In addition, corrosion of not only the bottom surface 111 of the water jacket 110 but also the side surfaces 112 and 113 can be prevented. Therefore, it is possible to further improve cooling performance and further prevent corrosion. Further, as compared with the case in which the side walls 43 and 44 are separated from the sealing portion 41 and the bottom portion 42, a simpler configuration and easier assembly can be realized.

In the present embodiment, the side walls 43 (the first side wall) and 44 (the second side wall) are disposed to face each other, and the plurality of heat dissipation fins 32 are surrounded by the bottom portion 42 and the side walls 43 and 44.

Therefore, by disposing the sealing material 40 in the clearance between the plurality of heat dissipation fins 32 and the bottom surface 111 and the side surfaces 112 and 113 of the water jacket 110, it is possible to improve cooling performance and prevent corrosion on all of the bottom surface 111, the side surface 112, and the side surface 113. Further, as compared with a case in which at least one of the two side walls 43 and 44 is separated from the sealing portion 41 and the bottom portion 42, a simpler configuration and easier assembly can be realized.

In the third modification (FIG. 7) and the fourth modification (FIG. 8) of the present embodiment, the sealing material 80 has the through holes 86 formed to allow screws adapted to fasten the heat dissipation base 31 of the cooler 30 and the water jacket 110 or 140 to be respectively inserted thereinto.

As a result, the sealing material 80 can be fixed and positioned by fixing the cooler 30 and the water jacket 110. Therefore, assembly can be further facilitated.

In addition, in the second modification (FIG. 6) of the present embodiment, the sealing material 70 includes at least one of the jacket-side convex portion 75, formed to protrude to the opposite side of the heat dissipation base 31 and inserted into the concave portion 139 provided in the water jacket 130, and the jacket-side concave portion, recessed toward the heat dissipation base 31 side and configured to allow the convex portion provided on the water jacket 130 to be inserted thereinto.

As a result, since the sealing material 70 can be positioned with respect to the water jacket 130, assembly can be further facilitated. In the water jacket 130 illustrated in FIG. 6 without the inner wall 116 and the outer wall 117 (refer to FIG. 3), the sealing portion 71 is not held by the inner wall 116 and the outer wall 117. Therefore, it is particularly effective to position the sealing material 70 with respect to the water jacket 130 by providing the jacket-side convex portion 75 (or the jacket-side concave portion).

In the first modification (FIG. 5), the second modification (FIG. 6), and the fourth modification (FIG. 8) of the present embodiment, in the water jackets 120, 130, and 140, portions of the sealing materials 40, 70, and 80 where the sealing portions 41, 71, and 81 are disposed (portions interposed between the heat dissipation base 31 and the water jackets 120, 130, and 140) form the same plane.

As a result, the inner wall 116 illustrated in FIG. 3 can be omitted from the water jackets 120, 130, and 140. Therefore, a simpler configuration can be obtained. In addition, the water jackets 120, 130, and 140 can be easily molded.

In the present embodiment (FIG. 3) and the third modification (FIG. 7), in the water jacket 110, portions (that is, regions on the inner peripheral side of the outer wall 117 on the upper surface of the water jacket 110) at which regions (that is, the front and rear portions of the sealing portions 41 and 81) connected to the side walls 43, 44, 83, and 84 of the sealing portions 41 and 81 of the sealing materials 40 and 80 are disposed form the same plane. In addition, the water jacket 110 has the inner wall 116 protruding toward the heat dissipation base 31 side on the inner peripheral edge of portions at which regions (that is, the left portion and the right portion of the sealing portion 41) not connected to the side walls 43, 44, 83, and 84 are disposed in the sealing portions 41 and 81 of the sealing materials 40 and 80.

As a result, in the regions of the sealing portions 41 and 81, which are connected to the side walls 43, 44, 83, and 84, the inner wall 116 of the water jacket 110 is omitted so as not to interfere with the sealing materials 40 and 80, so that the configuration can be further simplified. In addition, in the regions of the sealing portions 41 and 81, which are not connected to the side walls 43, 44, 83, and 84, the inner wall 116 holds the sealing materials 40 and 80, so that the sealing materials 40 and 80 can be positioned, and thus, assembly can be further facilitated.

Hereinafter, some inventions described in the specification and drawings of the present application will be additionally described.

### <Supplementary Note 1>

A semiconductor module including:
a semiconductor element;
a substrate having the semiconductor element mounted thereon;
a cooler including a heat dissipation base and a plurality of heat dissipation fins located on a side of the heat dissipation base, the side being opposite to the substrate, the cooler being attached to a water jacket configured to allow cooling water to flow through the plurality of heat dissipation fins; and
a sealing material integrally including a sealing portion in contact with a surface of the heat dissipation base of the cooler, the surface being located on the side opposite to the substrate, the sealing portion extending to a side opposite to the plurality of heat dissipation fins, a bottom portion having a portion facing tips of the plurality of heat dissipation fins, and connection portions each connecting the sealing portion to the bottom portion.

### <Supplementary Note 2>

The semiconductor module according to Supplementary Note 1, in which each of the connection portions of the sealing material includes a side wall extending in a flow direction in which the cooling water flows through the plurality of heat dissipation fins, the side wall having a portion facing the plurality of heat dissipation fins.

### <Supplementary Note 3>

The semiconductor module according to Supplementary Note 2, in which
the side wall includes a first side wall and a second side wall disposed to face the first side wall, and
the plurality of heat dissipation fins are surrounded by the bottom portion, the first side wall, and the second side wall.

### <Supplementary Note 4>

The semiconductor module according to Supplementary Note 1, in which the sealing material has a through hole configured to allow a screw to be inserted thereinto when the water jacket is attached to the cooler, the screw fastening the heat dissipation base of the cooler to the water jacket.

### <Supplementary Note 5>

The semiconductor module according to Supplementary Note 1, in which the sealing material includes at least one of a jacket-side convex portion protruding toward a side opposite to the heat dissipation base and a jacket-side concave portion recessed toward a side of the heat dissipation base.

### <Supplementary Note 6>

A semiconductor device including:
the semiconductor module according to any one of Supplementary Notes 1 to 5; and
the water jacket.

### <Supplementary Note 7>

The semiconductor device according to Supplementary Note 6, in which the water jacket has portions allowing the sealing portion of the sealing material to be disposed thereon, and a bottom surface allowing the bottom portion of the sealing material to be disposed thereon.

### <Supplementary Note 8>

The semiconductor device according to Supplementary Note 7, in which the portions of the water jacket, allowing the sealing portion of the sealing material to be disposed thereon, form the same plane.

### <Supplementary Note 9>

The semiconductor device according to Supplementary Note 7, in which
the water jacket has portions allowing regions of the sealing portion of the sealing material to be respectively disposed thereon, the regions respectively being connected to the connection portions, the portions of the water jacket forming the same plane, and
the water jacket has portions allowing regions of the sealing portion of the sealing material to be respectively disposed thereon, the regions not being connected to the connection portions, the portions of the water jacket having inner walls respectively formed on inner peripheral edges thereof, each of the inner walls protruding toward the heat dissipation base of the cooler.

As described above, the present invention has an effect of improving cooling performance and preventing corrosion with a simple configuration and easy assembly in a semiconductor module and a semiconductor device, and is particularly useful for an industrial or electrical inverter device.

What is claimed is:

1. A semiconductor module, comprising:
a cooler including a heat dissipation base having an upper surface and a lower surface opposite to the upper surface;
a substrate disposed on the upper surface of the heat dissipation base;
a semiconductor element mounted on the substrate;
the cooler further including a plurality of heat dissipation fins disposed on the lower surface, a water jacket, configured to allow cooling water to flow through the plurality of heat dissipation fins when attached to a lower surface side of the cooler, being attachable to the lower surface side of the cooler; and
a sealing part disposed on the lower surface of the heat dissipation base, wherein
the sealing part has a shape of recess configured to accommodate the plurality of heat dissipation fins, the sealing part integrally having
a sealing portion in contact with the lower surface of the heat dissipation base and extending away from the plurality of heat dissipation fins,
a bottom portion facing tips of the plurality of heat dissipation fins, and
a plurality of connection portions each connecting the sealing portion to the bottom portion.

2. The semiconductor module according to claim 1, wherein each of the plurality of connection portions of the sealing part includes a side wall that:
extends in a flow direction in which the cooling water flows through the plurality of heat dissipation fins when the water jacket is attached to the lower surface side of the cooler, and
faces the plurality of heat dissipation fins.

3. The semiconductor module according to claim 2, wherein
the plurality of connection portions are two in number,
the side wall of one of the two connection portions is a first side wall,
the side wall of the other one of the two connection portions is a second side wall, and
the first and second side walls face each other so that the plurality of heat dissipation fins are surrounded by the bottom portion, the first side wall and the second side wall.

4. The semiconductor module according to claim 1, wherein the sealing part has a through hole through which a screw, which fastens the heat dissipation base of the cooler to the water jacket, is to be inserted when the water jacket is attached to the cooler.

5. The semiconductor module according to claim 1, wherein the sealing part includes at least one of a jacket-side convex portion protruding in a direction away from the heat dissipation base and a jacket-side concave portion recessed in a direction approaching the heat dissipation base.

6. A semiconductor device, comprising:
the semiconductor module according to claim 1; and
the water jacket attached to the lower surface side of the cooler.

7. The semiconductor device according to claim 6, wherein the water jacket has a recess allowing the sealing portion of the sealing part to be disposed therein, and a bottom surface allowing the bottom portion of the sealing part to be disposed thereon.

8. The semiconductor device according to claim 7, wherein an upper surface of the sealing portion disposed in the recess of the water jacket is flush with an upper surface of the water jacket.

9. The semiconductor device according to claim 7, wherein
an upper surface of the sealing portion disposed in the recess of the water jacket is flush with an upper surface of the water jacket, and
the water jacket has inner walls, each of which protrudes toward the plurality of heat dissipation fins and is engaged with the sealing part at a corresponding position where the connection portions are not disposed.
